(19) United States
(12) Patent Application Publication
(10) Pub. No.: US 2024/0260437 A1
(43) Pub. Date: Aug. 1, 2024

(54) DISPLAY DEVICE AND METHOD FOR MANUFACTURING THE SAME

(71) Applicant: LG Display Co., Ltd., Seoul (KR)

(72) Inventors: Joon Young KWON, Paju-si (KR); Sang Jin Kim, Paju-si (KR)

(21) Appl. No.: 18/406,955

(22) Filed: Jan. 8, 2024

(30) Foreign Application Priority Data
Jan. 30, 2023 (KR) 10-2023-0012200

(51) Int. Cl. H10K 59/88; H10K 59/12; H10K 59/122; H10K 59/131; H10K 59/80

(52) U.S. Cl. CPC H10K 59/88; H10K 59/1201; H10K 59/122; H10K 59/131; H10K 59/873

(57) ABSTRACT

Disclosed are a display device and a method of manufacturing the same. A shorting bar of the display device includes a multi-layered conductive pattern structure disposed on a substrate and including two or more layers of conductive material patterns with at least one insulating film interposed therebetween, and a bank-spacer layer covering the multi-layered conductive pattern structure.

### CROSS-REFERENCE TO RELATED APPLICATION

This application claims the benefit of Republic of Korea Patent Application No. 10-2023-0012200, filed on Jan. 30, 2023, which is hereby incorporated by reference in its entirety.

### BACKGROUND

### Field of Technology

The present disclosure relates to a display device and a method of manufacturing the same.

### Discussion of the Related Art

Electroluminescent display devices are classified into inorganic electroluminescent display devices and organic light-emitting display devices depending on the material of an emission layer. Such an electroluminescent display device uses a self-emitting element, and thus has advantages such as a fast response time, high emission efficiency, high brightness, and a wide viewing angle. An organic light-emitting display device is configured such that each pixel has an organic light-emitting diode (OLED).

An organic light-emitting diode includes an organic electroluminescent compound layer configured to emit light in response to an electric field, and further includes a cathode and an anode disposed opposite each other with the organic electroluminescent compound layer interposed therebetween. The organic electroluminescent compound layer may include a hole injection layer (HIL), a hole transport layer (HTL), an emission material layer (EML), an electron transport layer (ETL), and an electron injection layer (EIL).

In the OLED, excitons are formed in an excitation process when holes and electrons injected from the cathode and the anode recombine in the emission material layer (EML), and light is emitted due to energy from the excitons.

The organic light-emitting display device controls a current flowing through the organic light-emitting diode using a thin-film transistor (TFT) to display an image.

The organic light-emitting display device includes a panel that displays an image through pixels disposed in a matrix with a plurality of gate lines and a plurality of data lines crossing each other.

A gate pad is disposed on one end of each of the plurality of gate lines, and a data pad is disposed on one end of each of the plurality of data lines.

In addition, in order to protect the gate pads and the data pads from static electricity, a gate shorting bar that electrically interconnects the gate pads and a data shorting bar that electrically interconnects the data pads are disposed.

The gate shorting bar and the data shorting bar prevent or reduce generation of static electricity during a manufacturing process. However, in the final process, the gate pads and the gate shorting bar (GSB) are disconnected from each other, and the data pads and the data shorting bar (DSB) are disconnected from each other.

Meanwhile, during the process of manufacturing the organic light-emitting display device, before a gate driving circuit or a data driving circuit is attached to a display panel, an auto-probe (AP) test is performed in order to detect defects in the display panel.

Since the aforementioned auto-probe (AP) test is performed using the gate shorting bar or the data shorting bar, a test pad for the auto-probe (AP) test needs to be formed on the gate shorting bar or the data shorting bar.

However, during an etching process for forming the test pad, a conductive material constituting the shorting bar may be exposed due to over-etching, leading to electrostatic burn.

### SUMMARY

Accordingly, the present disclosure is directed to a display device and a method of manufacturing the same that substantially obviate one or more problems due to limitations and disadvantages of the related art.

An object of embodiments of the present disclosure is to provide a display device configured such that a conductive material constituting a shorting bar is sufficiently covered by an insulating material, thereby preventing burn, and a method of manufacturing the same.

However, the objects to be accomplished by the present disclosure are not limited to the above-mentioned objects, and other objects not mentioned herein will be clearly understood by those skilled in the art from the following description.

Additional advantages, objects, and features of the disclosure will be set forth in part in the description which follows and in part will become apparent to those having ordinary skill in the art upon examination of the following or may be learned from practice of the disclosure. The objects and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a shorting bar of a display device includes a multi-layered conductive pattern structure disposed on a substrate and including two or more layers of conductive material patterns with at least one insulating film interposed therebetween, and a bank-spacer layer covering the multi-layered conductive pattern structure.

In another aspect of the present disclosure, a shorting bar of a display device includes a multi-layered conductive pattern structure disposed on a substrate and including two or more layers of conductive material patterns with at least one insulating film interposed therebetween, a bank layer covering the multi-layered conductive pattern structure, a first protective film formed on the bank layer, and an encapsulation layer formed on the first protective film.

In still another aspect of the present disclosure, a method of manufacturing a shorting bar includes forming a multi-layered conductive pattern structure on a substrate, the multi-layered conductive pattern structure including two or more layers of conductive material patterns with at least one insulating film interposed therebetween, and forming a bank-spacer layer on the multi-layered conductive pattern structure to cover the multi-layered conductive pattern structure.

In a further aspect of the present disclosure, a method of manufacturing a shorting bar includes forming a multi-layered conductive pattern structure on a substrate, the multi-layered conductive pattern structure including two or more layers of conductive material patterns with at least one insulating film interposed therebetween, forming a bank layer on the multi-layered conductive pattern structure to cover the multi-layered conductive pattern structure, forming a first protective film on the bank layer, forming an encapsulation layer on the first protective film to expose a predetermined portion of the first protective film, and removing the exposed predetermined portion of the first protective film.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram schematically showing an organic light-emitting display device according to an embodiment of the present disclosure;

FIG. 2 is a diagram showing a shorting bar extending in a COG area disposed in one side of an inactive area in the organic light-emitting display device in order to temporarily form an equipotential according to an embodiment of the present disclosure;

FIG. 3 is an equivalent circuit diagram of a sub-pixel SP according to an embodiment of the present disclosure;

FIGS. 4A to 4C are cross-sectional views showing a process of manufacturing an active area, a bezel area, and a shorting bar area according to a first embodiment of the present disclosure; and

FIGS. 5A to 5C are cross-sectional views showing a process of manufacturing an active area, a bezel area, and a shorting bar area according to a second embodiment of the present disclosure.

### DETAILED DESCRIPTION

Advantages and features of the present disclosure and methods for achieving them will be made clear from embodiments described below in detail with reference to the accompanying drawings. The present disclosure may, however, be embodied in many different forms, and should not be construed as being limited to the embodiments set forth herein. Rather, these embodiments are provided so that this disclosure will be thorough and complete, and will fully convey the scope of the disclosure to those skilled in the art. The present disclosure is defined only by the scope of the claims.

In the drawings for explaining the exemplary embodiments of the present disclosure, for example, the illustrated shape, size, ratio, angle, and number are given by way of example, and thus, are not limited to the disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear. The terms “comprises”, “includes”, and/or “has”, used in this specification, do not preclude the presence or addition of other elements unless used along with the term “only”. The singular forms are intended to include the plural forms as well, unless the context clearly indicates otherwise.

In the interpretation of constituent elements, the constituent elements are interpreted as including an error range even if there is no explicit description thereof.

In the description of the various embodiments, when describing positional relationships, for example, when the positional relationship between two parts is described using “on”, “above”, “below”, “next to”, or the like, one or more other parts may be located between the two parts unless the term “directly” or “closely” is used.

In the description of the various embodiments of the present disclosure, when describing temporal relationships, for example, when the temporal relationship between two actions is described using “after”, “subsequently”, “next”, “before”, or the like, the actions may not occur in succession unless the term “directly” or “just” is used therewith.

It may be understood that, although the terms “first”, “second”, etc. may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless otherwise mentioned.

The features of embodiments of the disclosure can be partially combined or entirely combined with each other, and can be technically interlocking-driven in various ways. The embodiments can be independently implemented, or can be implemented in conjunction with each other.

Hereinafter, a display device according to an embodiment of the present disclosure will be described in detail with reference to the accompanying drawings.

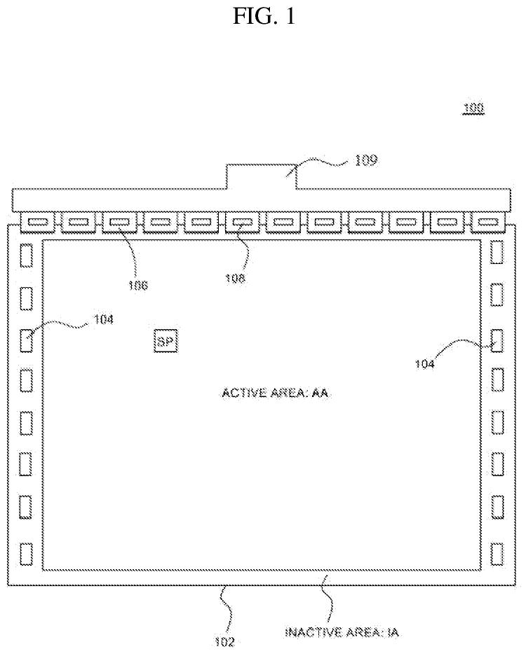

FIG. 1 is a diagram schematically showing an organic light-emitting display device 100 according to an embodiment of the present disclosure.

The organic light-emitting display device 100 includes a substrate 102. The substrate 102 is divided into an active area AA that displays an image and an inactive area IA. A plurality of sub-pixels SP that controls light are formed in the active area AA in order to display an image.

Each of the sub-pixels SP includes a transistor connected to a gate line and a data line, a capacitor configured to store a data signal DATA supplied through the transistor in the form of a data voltage, and a pixel circuit configured to operate in response to the data voltage stored in the capacitor.

The pixel circuit of each of the sub-pixels may be implemented in various forms using a capacitor Cst and a control device depending on the type, structure, and driving mode of a display device.

The organic light-emitting display device 100 includes a gate driving unit and a data driving unit, and displays an image by driving the plurality of sub-pixels SP in response to a gate signal supplied from the gate driving unit and a data signal supplied from the data driving unit.

The gate driving unit and the data driving unit are provided on one side of the substrate 102 or two opposite sides of the inactive area IA of the substrate 102 in the form of an integrated circuit (IC). Each of the gate driving unit and the data driving unit may be implemented as a plurality of drive integrated circuits (D-ICs).

In the embodiment shown in FIG. 1, the gate driving unit may be implemented as gate drive ICs 104 mounted in a chip-on-glass (COG) manner. In detail, the gate drive ICs 104 are directly bonded to a plurality of COG areas located in two opposite sides of the inactive area IA of the substrate 102. However, the present disclosure is not limited thereto, and the gate driving unit may be disposed in a gate-in-panel (GIP) manner or any other manner as known in the related art.

The data driving unit is implemented as data drive ICs 108 mounted in a chip-on-film (COF) manner on a flexible printed circuit board 106 connected to one side of the substrate 102, rather than being directly bonded to the substrate 102. Here, one side of the flexible printed circuit board 106 may be connected to the substrate 102, and the other side of the flexible printed circuit board 106 may be connected to a separate printed circuit board 109 on which a timing controller and a power supply are located. In this way, the flexible printed circuit board 106 may electrically connect the substrate 102 and the printed circuit board 109 to each other to transmit signals therebetween. For example, the flexible printed circuit board 106 may transmit various signals and power output from the timing controller and the power supply formed on the printed circuit board 109 to the gate driving unit and the data driving unit. An image processor may be mounted in the form of an integrated circuit (IC) on the printed circuit board 109 or another circuit board (or a system board) connected to the printed circuit board 109, but illustration thereof will be omitted.

In order to mount the gate drive ICs 104 on the substrate 102 by bonding the same to the substrate 102, a plurality of COG areas in which the gate drive ICs 104 are mounted is provided in one side or two opposite sides of the inactive area IA of the substrate 102. A plurality of input pads for input of an external signal into the gate drive ICs 104 and a plurality of output pads for output of signals from the gate drive ICs 104 may be located in each of the COG areas. The input pads and the output pads may be electrically connected to bumps of the gate drive ICs 104 to input an external signal into the gate drive ICs 104 and to output signals from the gate drive ICs 104. In this case, an adhesive such as an anisotropic conductive film (ACF) or a non-conductive paste (NCP) may be disposed between the COG areas in which the input pads and the output pads are formed and the gate drive ICs 104, whereby the gate drive ICs 104 may be bonded to the COG areas and electrically connected thereto.

Although the present disclosure has been described as being configured such that the gate drive ICs 104 are mounted on the substrate 102 by being bonded thereto in a COG manner, the substrate 102 is not limited to a glass substrate. In the embodiments of the present disclosure, the substrate 102 of the organic light-emitting display device 100 may be implemented not only as a glass substrate but also as any of various plastic substrates including any one of polyimide (PI), polycarbonate (PC), polynorbornene (PNB), polyethylene terephthalate (PET), polyethylene naphthalate (PEN), polyethersulfone (PES), etc., and driving units (e.g., gate drive ICs and data drive ICs) of the organic light-emitting display device 100 may be mounted on an inactive area of the plastic substrate by being directly bonded thereto.

It should be noted that the configuration of the organic light-emitting display device 100 described above with reference to FIG. 1 is intended to aid in understanding of the present disclosure, and the configuration and layout of the organic light-emitting display device 100 and various signals and power used for operation of the organic light-emitting display device 100 are not limited thereto. For example, the data driving unit as well as the gate driving unit may also be mounted on one side or two opposite sides of the inactive area of the substrate 102 in a COG manner by being directly bonded thereto. In this case, the output pads located in each of the COG areas in which the data drive ICs 108 are respectively mounted may be connected to the data lines DL via link lines to supply a data signal to the sub-pixels SP of the active area AA.

The organic light-emitting display device 100 may further include a driving unit that is directly formed on the inactive area IA in addition to the driving unit mounted on the inactive area IA in a bonding manner. For example, if the data driving unit of the organic light-emitting display device 100 is mounted on the inactive area IA of the substrate 102 by being directly bonded thereto in a COG manner, the gate driving unit may be provided in the inactive area IA of the substrate 102 in a gate-in-panel (GIP) manner.

The active area AA of the organic light-emitting display device 100 of the present disclosure may include at least two driving blocks. Here, the driving block is defined by lines (e.g., gate lines and data lines) for outputting a signal to the sub-pixels SP of the active area AA from one D-IC (e.g., a gate drive IC or a data drive IC) or a combination of D-ICs constituting a group (e.g., a pair of gate drive ICs or a pair of data drive ICs). That is, the active area AA may include lines for transmitting a signal applied from each of different D-ICs or a combination of different D-ICs and at least two COG blocks constituted by sub-pixels SP connected to the lines to be driven.

During the process of manufacturing the organic light-emitting display device 100, an equipotential formed between the COG Blocks may be removed before performing a test, such as an array test (ART)t, an auto probe (AP) test, or an illumination test, which requires application of different signals to the respective COG blocks or the respective gate lines of the COG blocks, and then the test or the subsequent manufacturing process may be performed.

In order to temporarily short-circuit the link lines 112 and the gate lines extending from the output pads in each COG area, the output pads may be connected to a shorting bar.

In the present specification, a connection part connecting the shorting bar to the pads and a connection part connecting the shorting bar to the equipotential line EQ_L in the COG area may be referred to as shorting lines. The shorting line between the shorting bar and the equipotential line EQ_L forming an equipotential between the COG blocks may be cut simultaneously with a process of cutting a portion of the shorting line between the output pads and the shorting bar in each COG area.

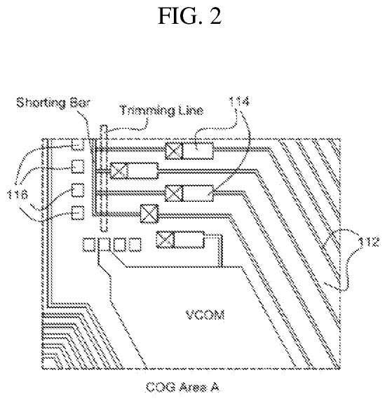

FIG. 2 is a diagram showing a shorting bar extending in a COG area COG Area_A disposed in one side of the inactive area in the organic light-emitting display device 100 in order to temporarily form an equipotential between the COG blocks according to an embodiment of the present disclosure.

The output pads 114 located in the COG area COG Area_A are respectively connected to the link lines 112. The link lines 112 may be connected to the gate lines configured to apply a signal for controlling on/off of transistors connected to the sub-pixels SP of the active area. Accordingly, gate signals output from the gate drive ICs 104 mounted on the COG area COG Area_A may be applied to the transistors connected to the sub-pixels SP of the active area AA via the output pads 114, the link lines 112, and the gate lines.

During various manufacturing and test processes performed while the organic light-emitting display device 100 including the COG-type driving units is manufactured, static electricity ESD may be introduced into the organic light-emitting display device 100. For example, the static electricity ESD may be introduced during various processes, for example, a process of feeding the substrate 102 or a process of forming the transistors on the substrate 102. If the static electricity ESD is introduced into various lines of the organic light-emitting display device 100, short circuit or disconnection may occur in the pads disposed adjacent to each other and the link lines 112, which may result in display defects in the organic light-emitting display device 100. Further, when a signal is applied to various lines and the pads of the organic light-emitting display device 100 in order to perform a test for detecting operation defects in the organic light-emitting display device 100, the link lines 112 are highly likely to be damaged due to a potential difference between the link lines 112 and between the lines disposed adjacent to each other. Therefore, a shorting bar may be used in order to temporarily short-circuit the output pads 114 in the COG areas and the link lines 112 extending therefrom.

The shorting bar may be located between the output pads 114 and the input pads 116 in the COG area.

In the organic light-emitting display device 100 including the COG-type driving unit, an equipotential may be temporarily formed between the output pad 114, the link lines 112, and the gate lines in each COG block using the shorting bar, as shown in FIG. 2.

In order for the organic light-emitting display device 100 to finally output an image, a gate signal needs to be applied to the individual gate lines of the organic light-emitting display device. Therefore, the output pads 114 need to be insulated from the shorting bar in the completely manufactured organic light-emitting display device 100.

To this end, eventually, the shorting lines between the output pads 114 and the shorting bar may be removed from a trimming line area so that the output pads 114 and the shorting bar are electrically insulated from each other.

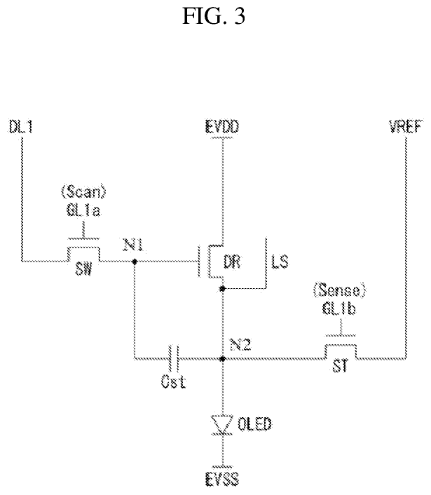

FIG. 3 is an equivalent circuit diagram of a sub-pixel SP according to an embodiment of the present disclosure.

FIG. 3 merely illustrates one exemplary sub-pixel circuit. Hereinafter, for convenience of explanation, an organic light-emitting display device having the pixel circuit structure shown in FIG. 3 will be described.

Referring to FIG. 3, each of the plurality of sub-pixels P may include a pixel circuit having a driving transistor DR and a light-emitting diode OLED that is driven by the pixel circuit.

The pixel circuit may control a driving current flowing through the light-emitting diode OLED to drive the light-emitting diode OLED. The pixel circuit may include a driving transistor DR, a switching transistor SW, a sensing transistor ST, and a capacitor Cst.

Each of the transistors DR, SW, and ST may include a first electrode, a second electrode, and a gate electrode. One of the first electrode and the second electrode may be a source electrode, and the other of the first electrode and the second electrode may be a drain electrode.

Each of the transistors DR, SW, and ST may be a P-type thin-film transistor or an N-type thin-film transistor. In the embodiment shown in FIG. 3, the transistors DR, SW, and ST are implemented as N-type thin-film transistors. However, the disclosure is not limited thereto. In some embodiments, all or some of the transistors DR, SW, and ST may be P-type thin-film transistors or N-type thin-film transistors. Further, the N-type thin-film transistor may be an oxide thin-film transistor, and the P-type thin-film transistor may be a polycrystalline silicon thin-film transistor, but the present disclosure is not limited thereto. The oxide thin-film transistor including an oxide semiconductor layer formed of an oxide semiconductor material has an excellent effect of blocking a leakage current and has a relatively low fabrication cost as compared with a polycrystalline silicon thin-film transistor. For example, the oxide semiconductor layer may include indium gallium zinc oxide (IGZO), zinc oxide (ZnO), tin oxide (SnO2), copper oxide (Cu2O), nickel oxide (NiO), indium tin zinc oxide (ITZO) and/or indium aluminum zinc oxide (IAZO). The embodiments of the present disclosure are not limited thereto. In the embodiment of the present disclosure, to reduce a power consumption and a fabrication cost, the driving transistor DR and at least one of other transistors such as the switching transistor SW and the sensing transistor ST may be fabricated using an oxide semiconductor layer.

The polycrystalline silicon thin-film transistor using a polycrystalline semiconductor layer including a polycrystalline semiconductor material, for example, polycrystalline silicon (poly-Si) has a relatively high operation speed and an excellent reliability. In various embodiments of the present disclosure, one of the other transistors may include a polycrystalline semiconductor layer and the others of the other transistors may include an oxide semiconductor layer.

The transistors DR, SW, and ST are turned on in response to a high voltage.

In addition, a compensation transistor for compensating for a threshold voltage Vth of the driving transistor DR, an emission control transistor for controlling an emission time, a bias transistor for supplying a bias voltage, and an initialization transistor for initializing the sub-pixel may be further included.

The driving transistor DR may include a first electrode connected to a high-potential driving voltage EVDD supply line, a second electrode connected to a second node N2, and a gate electrode connected to a first node N1. The driving transistor DR may provide a driving current corresponding to the voltage of the first node N1 (or a data voltage Vdata stored in the capacitor Cst, which will be described later) to the light-emitting diode OLED.

The switching transistor SW may include a first electrode connected to a data line DL1, a second electrode connected to the first node N1, and a gate electrode connected to a first scan line GL1a. The switching transistor SW may perform switching operation to store a data signal supplied through the data line DL1 in the capacitor Cst in the form of a data voltage in response to a scan signal supplied through the first scan line GL1a.

The sensing transistor ST may include a first electrode connected to the second node N2, a second electrode connected to a reference line VREF, and a gate electrode connected to a second scan line GL1b. The sensing transistor ST may sense the threshold voltage Vth of the driving transistor DR through the reference line VREF in response to a sensing signal Sense supplied through the second scan line GL1b.

The light-emitting diode OLED may include an anode (or anode electrode) and a cathode (or cathode electrode). The anode electrode of the light-emitting diode OLED may be connected to the second node N2, and the cathode electrode of the light-emitting diode OLED may be connected to a low-potential driving voltage EVSS supply line. The organic light-emitting diode OLED may operate to emit light in response to a driving current formed by the driving transistor DR.

It is to be noted that FIG. 3 shows an example of the sub-pixel circuit of a display device, but the present disclosure is not limited thereto. The sub-pixel structure may further include one or more transistors, or may further include one or more capacitors, if needed. For example, 3T1C, 4T1C, 5T1C, 3T2C, 4T2C, 5T2C, 6T2C, 7T1C, 7T2C, 8T2C and the like structures are also possible, and more or less transistors and capacitors could be included. Alternatively, each of the subpixels in the display area may have the same sub-pixel structure, and some of the subpixels may have the different sub-pixel structures.

A method of manufacturing the shorting bar described above will be described below.

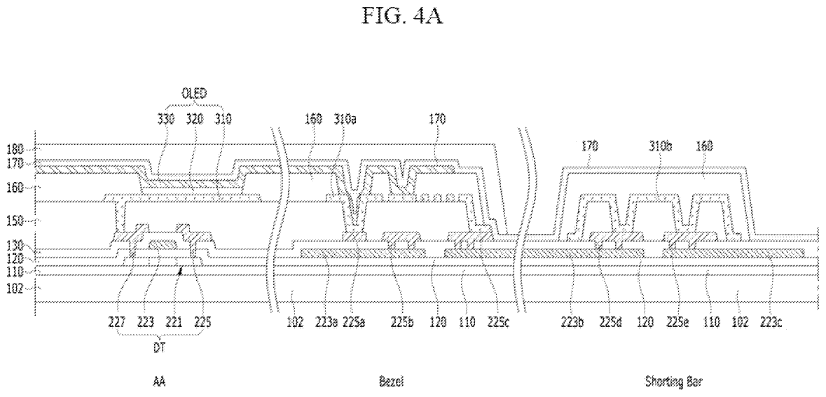

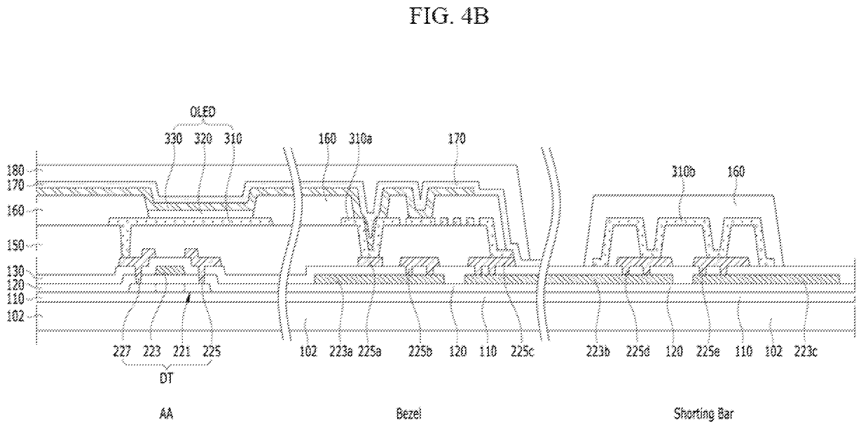

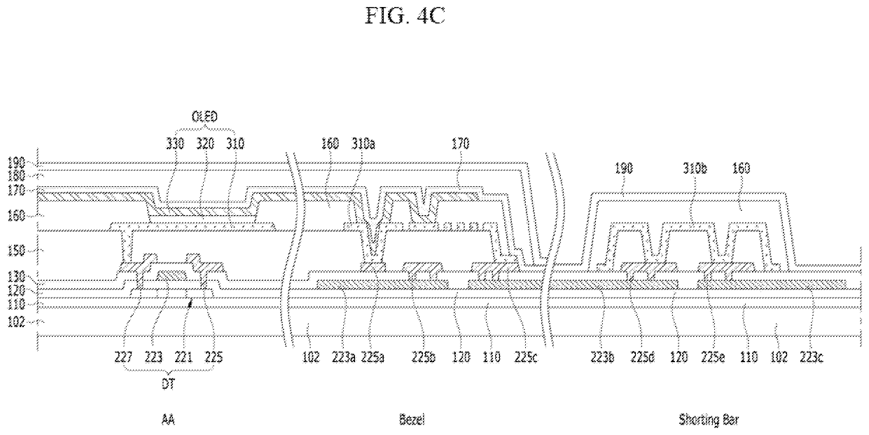

FIGS. 4A to 4C are cross-sectional views showing a process of manufacturing an active area AA, a bezel area Bezel, and a shorting bar area according to a first embodiment of the present disclosure.

As shown in FIG. 4A, a buffer film 110 is formed on a substrate 102 over the active area AA, the bezel area Bezel, and the shorting bar area. The buffer film 110 may prevent or reduce contamination due to the substrate 102 during a process of forming the pixel driving circuit located in each pixel area SP.

A semiconductor pattern 221 may be formed on the buffer film 110 in the active area AA.

A gate insulating film 120 may be formed on the buffer film 110 including the semiconductor pattern 221 over the active area AA, the bezel area Bezel, and the shorting bar area.

The semiconductor pattern 221 may include amorphous silicon (a-Si), polycrystalline silicon (Poly-Si), or an oxide semiconductor such as IGZO. The semiconductor pattern 221 may include a drain region, a channel region, and a source region. The channel region may be located between the drain region and the source region. The drain region and the source region may have a lower resistance than the channel region. For example, the drain region and the source region may include a conductorized region of the oxide semiconductor. The channel region may be a non-conductorized region of the oxide semiconductor.

A gate electrode 223 may be formed on the gate insulating film 120 in the active area AA.

The gate electrode 223 may be located over the semiconductor pattern 221. For example, the gate electrode 223 may overlap the channel region of the semiconductor pattern 221. The drain region and the source region of the semiconductor pattern 221 may be located outside the gate electrode 223.

The gate electrode 223 may include a conductive material. For example, the gate electrode 223 may include a metal such as aluminum (Al), chromium (Cr), copper (Cu), molybdenum (Mo), titanium (Ti), or tungsten (W).

First to third conductive material patterns 223a, 223b, and 223c may be formed on the gate insulating film 120 in the bezel area and the shorting bar area. The first to third conductive material patterns 223a, 223b, and 223c may be made of the same material as the gate electrode 223 through one mask process. As a result, a number of the mask processes may be reduced.

The first conductive material pattern 223a may be formed in the bezel area Bezel, the second conductive material pattern 223b may be formed in the bezel area Bezel and the shorting bar area, and the third conductive material pattern 223c may be formed in the shorting bar area.

An interlayer insulating film 130 may be formed on the gate insulating film 120 including the gate electrode 223 and the first to third conductive material patterns 223a, 223b, and 223c over the active area AA, the bezel area Bezel, and the shorting bar area.

The interlayer insulating film 130 may include an insulating material. For example, the interlayer insulating film 130 may include an inorganic insulating material such as silicon oxide (SiOx) or silicon nitride (SiNx).

A source electrode 225 and a drain electrode 227 may be formed on the interlayer insulating film 130 in the active area AA.

The source electrode 225 and the drain electrode 227 may include a conductive material. For example, the source electrode 225 and the drain electrode 227 may include a metal such as aluminum (Al), chromium (Cr), copper (Cu), molybdenum (Mo), titanium (Ti), or tungsten (W). The source electrode 225 and the drain electrode 227 may include a material different from that of the gate electrode 223.

The source electrode 225 and the drain electrode 227 may be electrically connected to the source region and the drain region of the semiconductor pattern 221 through contact holes formed in the interlayer insulating film 130 and the gate insulating film 120.

Therefore, the semiconductor pattern 221, the gate electrode 223, the source electrode 225, and the drain electrode 227 may be provided in the active area AA to form a thin-film transistor. The thin-film transistor may be the driving transistor DR described with reference to FIG. 3.

Fourth to eighth conductive material patterns 225a, 225b, 225c, 225d, and 225e may be formed on the interlayer insulating film 130 in the bezel area Bezel and the shorting bar area. The fourth to eighth conductive material patterns 225a, 225b, 225c, 225d, and 225e may be made of the same material as the source electrode 225 and the drain electrode 227 through one mask process. As a result, a number of the mask processes may be reduced.

The fourth to sixth conductive material patterns 225a, 225b, and 225c may be formed in the bezel area Bezel, and the seventh and eighth conductive material patterns 225d and 225e may be formed in the shorting bar area.

The fifth conductive material pattern 225b may be electrically connected to the first conductive material pattern 223a through another contact hole formed in the interlayer insulating film 130, and the sixth conductive material pattern 225c may be electrically connected to one end of the second conductive material pattern 223b through still another contact hole formed in the interlayer insulating film 130.

The seventh conductive material pattern 225d may be electrically connected to the other end of the second conductive material pattern 223b through still another contact hole formed in the interlayer insulating film 130, and the eighth conductive material pattern 225e may be electrically connected to the third conductive material pattern 223c through still another contact hole formed in the interlayer insulating film 130.

The fourth and sixth conductive material patterns 225a and 225c may be the low-potential voltage EVSS supply lines described with reference to FIG. 3, and the fifth conductive material pattern 225b may be the high-potential voltage EVDD supply line described with reference to FIG. 3.

A planarization film 150 may be formed on the interlayer insulating film 130 including the source electrode 225, the drain electrode 227, and the fourth to eighth conductive material patterns 225a, 225b, 225c, 225d, and 225e over the active area AA, the bezel area Bezel, and the shorting bar area.

The upper surface of the planarization film 150 may be a flat surface. The planarization film 150 may include an insulating material. The planarization film 150 may include an organic insulating material.

In the bezel area Bezel and the shorting bar area, the planarization film 150 may be patterned to cover the fourth to eighth conductive material patterns 225a, 225b, 225c, 225d, and 225e and to open the other elements.

Although not shown in the drawings, a protective film may be further formed between the interlayer insulating film 130 and the planarization film 150.

A first electrode 310 of the light-emitting diode is formed on the planarization film 150 in the active area AA. The first electrode 310 may be electrically connected to the drain electrode 227 of the thin-film transistor through a contact hole formed in the planarization film 150.

The first electrode 310 may include a conductive material. The first electrode 310 may include a material having relatively high reflectivity. For example, the first electrode 310 may include a metal such as aluminum (Al) or silver (Ag). The first electrode 310 may have a multilayer structure. For example, the first electrode 310 may have a structure in which a reflective electrode made of a metal is located between transparent electrodes made of a transparent conductive material such as ITO or IZO.

Ninth and tenth conductive material patterns 310a and 310b may be formed on the planarization film 150 in the bezel area Bezel and the shorting bar area. The ninth and tenth conductive material patterns 310a and 310b may be made of the same material as the first electrode 310 through one mask process. As a result, a number of the mask processes may be reduced.

The ninth conductive material pattern 310a may be electrically connected to the fourth conductive material pattern 225a through another contact hole formed in the planarization film 150, and the tenth conductive material pattern 310b may be electrically connected to the seventh and eighth conductive material patterns 225d and 225e through still other contact holes formed in the planarization film 150.

A bank-spacer layer 160 may be formed on the planarization film 150 including the first electrode 310 and the ninth and tenth conductive material patterns 310a and 310b over the active area AA, the bezel area Bezel, and the shorting bar area.

The bank-spacer layer 160 may include an insulating material. For example, the bank-spacer layer 160 may include an organic insulating material. The bank-spacer layer 160 may include a material different from that of the planarization film 150. For example, the bank-spacer layer 160 may include an organic insulating material such as acryl resin, epoxy resin, phenolic resin, polyamide resin, and/or polyimide resin, etc. Alternatively, the bank-spacer layer 160 may include an inorganic insulating material such as silicon nitride, aluminum nitride, zirconium nitride, titanium nitride, hafnium nitride, tantalum nitride, silicon oxide, aluminum oxide, or titanium oxide, etc. In another example, the bank-spacer layer 160 may be made of an insulating material containing a black material. The bank BNK may be made of, for example, a transparent carbon-based mixture. Specifically, the bank BNK may contain carbon black, but is not limited thereto. The bank may also be made of a transparent insulating material.

In the active area AA, the bank-spacer layer 160 may have an opening serving as an emission area on the first electrode 310. In the shorting bar area, the bank-spacer layer 160 may completely cover the tenth conductive material pattern 310b.

An emission layer 320 may be formed on the first electrode 310 in the active area AA.

The emission layer 320 may generate light having brightness corresponding to a voltage difference between the first electrode 310 and a second electrode 330 to be formed later. The emission layer 320 may include an emission material layer (EML) including an emission material. The emission material may include an organic material, an inorganic material, or a hybrid material.

The emission layer 320 may have a multilayer structure. For example, the emission layer 320 may further include at least one of a hole injection layer (HIL), a hole transport layer (HTL), an electron transport layer (ETL), or an electron injection layer (EIL).

A second electrode 330 of the light-emitting diode may be formed over the active area AA and the bezel area Bezel.

The second electrode 330 may include a conductive material. The second electrode 330 may include a material different from that of the first electrode 310. The transmittance of the second electrode 330 may be greater than the transmittance of the first electrode 310. For example, the second electrode 330 may be a transparent electrode made of a transparent conductive material such as ITO or IZO or a thin translucent electrode made of a metal such as Ag or Mg. Accordingly, in the organic light-emitting display device according to the embodiment of the present disclosure, light generated by the emission layer 320 may be emitted through the second electrode 330.

The first electrode 310, the emission layer 320, and the second electrode 330 may constitute the light-emitting diode OLED.

In the bezel area Bezel, the second electrode 330 may be electrically connected to the ninth conductive material pattern 310a through a contact hole formed in the bank-spacer layer 160.

A first protective film 170 may be formed on the bank-spacer layer 160 including the second electrode 330 over the active area AA, the bezel area Bezel, and the shorting bar area.

The first protective film 170 may include an insulating material. For example, the first protective film 170 may include an inorganic insulating material such as silicon oxide (SiOx) or silicon nitride (SiNx).

Then, an encapsulation layer 180 may be formed on the first protective film 170 over the active area AA and the bezel area Bezel. The encapsulation layer 180 may prevent damage to the light-emitting diode OLED located in the pixel area SP due to external moisture and impact. For example, the light-emitting diode OLED in each pixel area SP may be completely covered by the encapsulation layer 180. The encapsulation layer 180 may have a multilayer structure. For example, although not shown in the drawings, the encapsulation layer 180 may have a structure in which a first encapsulation layer, a second encapsulation layer, and a third encapsulation layer are stacked one above another. The first encapsulation layer, the second encapsulation layer, and the third encapsulation layer may include an insulating material. The second encapsulation layer may include a material different from that of the first encapsulation layer and the third encapsulation layer. For example, the first encapsulation layer and the third encapsulation layer may include an inorganic insulating material such as silicon oxide (SiOx) or silicon nitride (SiNx), and the second encapsulation layer may include an organic insulating material. Accordingly, in the organic light-emitting display device according to the embodiment of the present disclosure, it may be possible to effectively prevent or reduce damage to the light-emitting diode OLED located in each pixel area SP due to external moisture and impact.

The encapsulation layer 180 may not be formed in the shorting bar area.

As shown in FIG. 4B, the first protective film 170 in the shorting bar area may be selectively removed. The reason for selectively removing the first protective film 170 in the shorting bar area is to form the test pad described above.

A dry etching process may be performed on the first protective film 170 in the shorting bar area.

While the dry etching process is performed on the first protective film 170 in the shorting bar area in order to form the test pad, even if over-etching occurs, it may be possible to prevent or at least reduce exposure of the tenth conductive material pattern 310b to the outside or damage to the tenth conductive material pattern 310b because the bank-spacer layer 160 is formed to be thick on the tenth conductive material pattern 310b.

Therefore, it may be possible to prevent or at least reduce occurrence of electrostatic burn and introduction of static electricity ESD into the organic light-emitting display device 100 during various manufacturing and test processes. That is, the internal circuit of the organic light-emitting display device 100 may be protected from static electricity.

As shown in FIG. 4C, a second protective film 190 may be formed over the active area AA, the bezel area Bezel, and the shorting bar area.

The second protective film 190 may include an insulating material. For example, the second protective film 190 may include an inorganic insulating material such as silicon oxide (SiOx) or silicon nitride (SiNx).

Although not shown in the drawings, a touch sensor may be further formed on the second protective film 190 in the active area AA.

The second protective film 190 may serve as a touch insulating film formed between the touch sensor and the encapsulation layer 180.

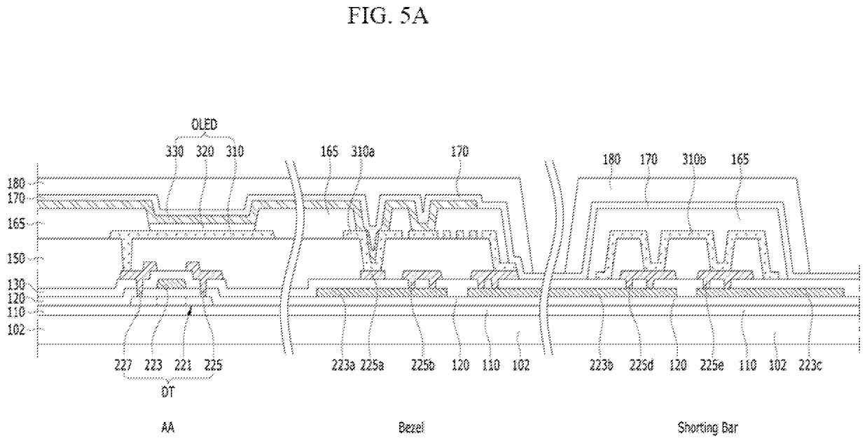

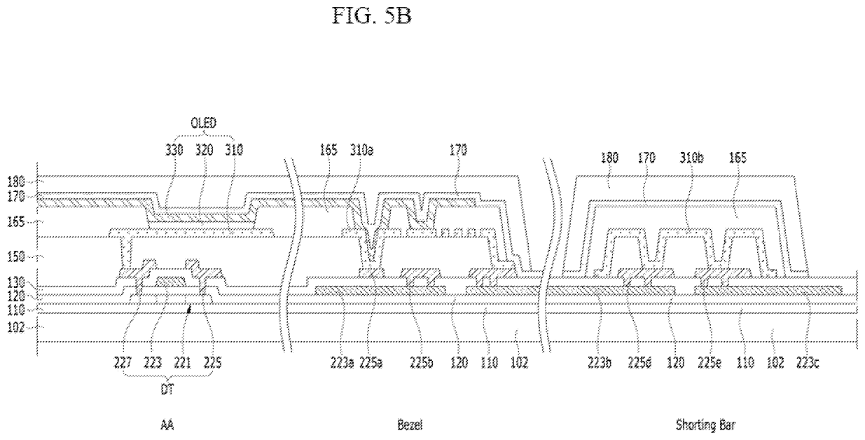

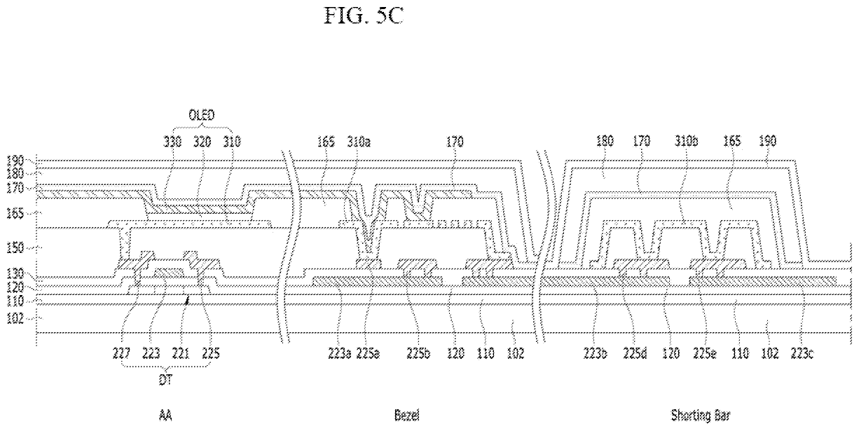

FIGS. 5A to 5C are cross-sectional views showing a process of manufacturing an active area AA, a bezel area Bezel, and a shorting bar area according to a second embodiment of the present disclosure.

As shown in FIG. 5A, a buffer film 110 is formed on a substrate 102 over the active area AA, the bezel area Bezel, and the shorting bar area. The buffer film 110 may prevent or reduce contamination due to the substrate 102 during a process of forming the pixel driving circuit located in each pixel area SP.

A semiconductor pattern 221 may be formed on the buffer film 110 in the active area AA.

A gate insulating film 120 may be formed on the buffer film 110 including the semiconductor pattern 221 over the active area AA, the bezel area Bezel, and the shorting bar area.

The semiconductor pattern 221 may include amorphous silicon (a-Si), polycrystalline silicon (Poly-Si), or an oxide semiconductor such as IGZO. The semiconductor pattern 221 may include a drain region, a channel region, and a source region. The channel region may be located between the drain region and the source region. The drain region and the source region may have a lower resistance than the channel region. For example, the drain region and the source region may include a conductorized region of the oxide semiconductor. The channel region may be a non-conductorized region of the oxide semiconductor.

A gate electrode 223 may be formed on the gate insulating film 120 in the active area AA.

The gate electrode 223 may be located on the semiconductor pattern 221. For example, the gate electrode 223 may overlap the channel region of the semiconductor pattern 221. The drain region and the source region of the semiconductor pattern 221 may be located outside the gate electrode 223.

The gate electrode 223 may include a conductive material. For example, the gate electrode 223 may include a metal such as aluminum (Al), chromium (Cr), copper (Cu), molybdenum (Mo), titanium (Ti), or tungsten (W).

First to third conductive material patterns 223a, 223b, and 223c may be formed on the gate insulating film 120 in the bezel area Bezel and the shorting bar area. The first to third conductive material patterns 223a, 223b, and 223c may be made of the same material as the gate electrode 223.

The first conductive material pattern 223a may be formed in the bezel area Bezel, the second conductive material pattern 223b may be formed in the bezel area Bezel and the shorting bar area, and the third conductive material pattern 223c may be formed in the shorting bar area.

An interlayer insulating film 130 may be formed on the gate insulating film 120 including the gate electrode 223 and the first to third conductive material patterns 223a, 223b, and 223c over the active area AA, the bezel area Bezel, and the shorting bar area.

The interlayer insulating film 130 may include an insulating material. For example, the interlayer insulating film 130 may include an inorganic insulating material such as silicon oxide (SiOx) or silicon nitride (SiNx).

A source electrode 225 and a drain electrode 227 may be formed on the interlayer insulating film 130 in the active area AA.

The source electrode 225 and the drain electrode 227 may include a conductive material. For example, the source electrode 225 and the drain electrode 227 may include a metal such as aluminum (Al), chromium (Cr), copper (Cu), molybdenum (Mo), titanium (Ti), or tungsten (W). The source electrode 225 and the drain electrode 227 may include a material different from that of the gate electrode 223.

The source electrode 225 and the drain electrode 227 may be electrically connected to the source region and the drain region of the semiconductor pattern 221 through contact holes formed in the interlayer insulating film 130 and the gate insulating film 120.

Therefore, the semiconductor pattern 221, the gate electrode 223, the source electrode 225, and the drain electrode 227 may be provided in the active area AA to form a thin-film transistor. The thin-film transistor may be the driving transistor DR described with reference to FIG. 3.

Fourth to eighth conductive material patterns 225a, 225b, 225c, 225d, and 225e may be formed on the interlayer insulating film 130 in the bezel area Bezel and the shorting bar area. The fourth to eighth conductive material patterns 225a, 225b, 225c, 225d, and 225e may be made of the same material as the source electrode 225 and the drain electrode 227.

The fourth to sixth conductive material patterns 225a, 225b, and 225c may be formed in the bezel area Bezel, and the seventh and eighth conductive material patterns 225d and 225e may be formed in the shorting bar area.

The fifth conductive material pattern 225b may be electrically connected to the first conductive material pattern 223a through another contact hole formed in the interlayer insulating film 130, and the sixth conductive material pattern 225c may be electrically connected to one end of the second conductive material pattern 223b through still another contact hole formed in the interlayer insulating film 130.

The seventh conductive material pattern 225d may be electrically connected to the other end of the second conductive material pattern 223b through still another contact hole formed in the interlayer insulating film 130, and the eighth conductive material pattern 225e may be electrically connected to the third conductive material pattern 223c through still another contact hole formed in the interlayer insulating film 130.

The fourth and sixth conductive material patterns 225a and 225c may be the low-potential voltage EVSS supply lines described with reference to FIG. 3, and the fifth conductive material pattern 225b may be the high-potential voltage EVDD supply line described with reference to FIG. 3.

A planarization film 150 may be formed on the interlayer insulating film 130 including the source electrode 225, the drain electrode 227, and the fourth to eighth conductive material patterns 225a, 225b, 225c, 225d, and 225e over the active area AA, the bezel area Bezel, and the shorting bar area.

The upper surface of the planarization film 150 may be a flat surface. The planarization film 150 may include an insulating material. The planarization film 150 may include an organic insulating material.

In the bezel area Bezel and the shorting bar area, the planarization film 150 may be patterned to cover the fourth to eighth conductive material patterns 225a, 225b, 225c, 225d, and 225e and to open the other elements.

Although not shown in the drawings, a protective film may be further formed between the interlayer insulating film 130 and the planarization film 150.

A first electrode 310 of the light-emitting diode is formed on the planarization film 150 in the active area AA. The first electrode 310 may be electrically connected to the drain electrode 227 of the thin-film transistor through a contact hole formed in the planarization film 150.

The first electrode 310 may include a conductive material. The first electrode 310 may include a material having relatively high reflectivity. For example, the first electrode 310 may include a metal such as aluminum (Al) or silver (Ag). The first electrode 310 may have a multilayer structure. For example, the first electrode 310 may have a structure in which a reflective electrode made of a metal is located between transparent electrodes made of a transparent conductive material such as ITO or IZO.

Ninth and tenth conductive material patterns 310a and 310b may be formed on the planarization film 150 in the bezel area Bezel and the shorting bar area. The ninth and tenth conductive material patterns 310a and 310b may be made of the same material as the first electrode 310.

The ninth conductive material pattern 310a may be electrically connected to the fourth conductive material pattern 225a through another contact hole formed in the planarization film 150, and the tenth conductive material pattern 310b may be electrically connected to the seventh and eighth conductive material patterns 225d and 225e through still other contact holes formed in the planarization film 150.

A bank layer 165 may be formed on the planarization film 150 including the first electrode 310 and the ninth and tenth conductive material patterns 310a and 310b over the active area AA, the bezel area Bezel, and the shorting bar area.

The bank layer 165 may include an insulating material. For example, the bank layer 165 may include an organic insulating material. The bank layer 165 may include a material different from that of the planarization film 150.

In the active area AA, the bank layer 165 may have an opening serving as an emission area on the first electrode 310. In the shorting bar area, the bank layer 165 may completely cover the tenth conductive material pattern 310b.

An emission layer 320 may be formed on the first electrode 310 in the active area AA.

The emission layer 320 may generate light having brightness corresponding to a voltage difference between the first electrode 310 and a second electrode 330 to be formed later. The emission layer 320 may include an emission material layer (EML) including an emission material. The emission material may include an organic material, an inorganic material, or a hybrid material.

The emission layer 320 may have a multilayer structure. For example, the emission layer 320 may further include at least one of a hole injection layer (HIL), a hole transport layer (HTL), an electron transport layer (ETL), or an electron injection layer (EIL).

A second electrode 330 of the light-emitting diode may be formed over the active area AA and the bezel area Bezel.

The second electrode 330 may include a conductive material. The second electrode 330 may include a material different from that of the first electrode 310. The transmittance of the second electrode 330 may be greater than the transmittance of the first electrode 310. For example, the second electrode 330 may be a transparent electrode made of a transparent conductive material such as ITO or IZO or a thin translucent electrode made of a metal such as Ag or Mg. Accordingly, in the organic light-emitting display device according to the embodiment of the present disclosure, light generated by the emission layer 320 may be emitted through the second electrode 330.

The first electrode 310, the emission layer 320, and the second electrode 330 may constitute the light-emitting diode OLED.

In the bezel area Bezel, the second electrode 330 may be electrically connected to the ninth conductive material pattern 310a through a contact hole formed in the bank layer 165.

A first protective film 170 may be formed on the bank layer 165 including the second electrode 330 over the active area AA, the bezel area Bezel, and the shorting bar area.

The first protective film 170 may include an insulating material. For example, the first protective film 170 may include an inorganic insulating material such as silicon oxide (SiOx) or silicon nitride (SiNx).

Then, an encapsulation layer 180 may be formed on the first protective film 170 over the active area AA, the bezel area Bezel, and the shorting bar area. The encapsulation layer 180 may prevent or at least reduce damage to the light-emitting diode OLED located in the pixel area SP due to external moisture and impact. For example, the light-emitting diode OLED in each pixel area SP may be completely covered by the encapsulation layer 180. The encapsulation layer 180 may have a multilayer structure. For example, although not shown in the drawings, the encapsulation layer 180 may have a structure in which a first encapsulation layer, a second encapsulation layer, and a third encapsulation layer are stacked one above another. The first encapsulation layer, the second encapsulation layer, and the third encapsulation layer may include an insulating material. The second encapsulation layer may include a material different from that of the first encapsulation layer and the third encapsulation layer. For example, the first encapsulation layer and the third encapsulation layer may include an inorganic insulating material such as silicon oxide (SiOx) or silicon nitride (SiNx), and the second encapsulation layer may include an organic insulating material. Accordingly, in the organic light-emitting display device according to the embodiment of the present disclosure, it may be possible to effectively prevent or reduce damage to the light-emitting diode OLED located in each pixel area SP due to external moisture and impact.

In the shorting bar area, the encapsulation layer 180 may be formed such that a portion of the first protective film 170 is exposed.

As shown in FIG. 5B, in the shorting bar area, the first protective film 170 exposed by the encapsulation layer 180 may be selectively removed. The reason for selectively removing the first protective film 170 in the shorting bar area is to form the test pad described above.

A dry etching process may be performed on the first protective film 170 in the shorting bar area.

While the dry etching process is performed on the first protective film 170 in the shorting bar area in order to form the test pad, even if over-etching occurs, it may be possible to prevent or reduce exposure of the tenth conductive material pattern 310b to the outside or damage to the tenth conductive material pattern 310b because the bank layer 165 and the encapsulation layer 180 cover the tenth conductive material pattern 310b.

Therefore, it may be possible to prevent or reduce occurrence of electrostatic burn and introduction of static electricity ESD into the organic light-emitting display device 100 during various manufacturing and test processes. That is, the internal circuit of the organic light-emitting display device 100 may be protected from static electricity.

As shown in FIG. 5C, a second protective film 190 may be formed over the active area AA, the bezel area Bezel, and the shorting bar area.

The second protective film 190 may include an insulating material. For example, the second protective film 190 may include an inorganic insulating material such as silicon oxide (SiOx) or silicon nitride (SiNx).

Although not shown in the drawings, a touch sensor may be further formed on the second protective film 190 in the active area AA.

The second protective film 190 may serve as a touch insulating film formed between the touch sensor and the encapsulation layer 180.

As described above, in the method of manufacturing the shorting bar according to the present disclosure, while a dry etching process is performed on the first protective film 170 in the shorting bar area in order to form a test pad, even if over-etching occurs, it may be possible to prevent or reduce exposure of the tenth conductive material pattern 310b to the outside or damage to the tenth conductive material pattern 310b because the thick bank-spacer layer 160 covers the tenth conductive material pattern 310b or the bank layer 165 and the encapsulation layer 180 cover the tenth conductive material pattern 310b.

Therefore, it may be possible to prevent or at least reduce occurrence of electrostatic burn and introduction of static electricity ESD into the organic light-emitting display device 100 during various manufacturing and test processes. That is, the internal circuit of the organic light-emitting display device 100 may be protected from static electricity.

It is to be noted that, although FIGS. 4A to 4C and 5A to 5C show some examples of the specific structure of the display device, the present disclosure is not limited thereto. For example, one or more layers shown in FIGS. 4A to 4C or 5A to 5C may be omitted, changed, or replaced with one or more other layers, and the present disclosure is not limited thereto.

In addition, although each of FIGS. 4A to 4C and 5A to 5C shows a specific structure of the shorting bar as including three layers of conductive material patterns with two insulating films interposed therebetween, the present application is not limited thereto. For example, the shorting bar may include two layers of conductive material patterns, or four or more layers of conductive material patterns. As such, such two or more layers of conductive material patterns with at least one insulating film interposed therebetween may be referred to as a multi-layered conductive pattern structure hereinafter, but the present application is not limited thereto.

The embodiments of the present disclosure described above will be described below in brief.

The shorting bar of the display device according to one embodiment of the present disclosure may include a multi-layered conductive pattern structure disposed on a substrate and including two or more layers of conductive material patterns with at least one insulating film interposed therebetween, and a bank-spacer layer covering the multi-layered conductive pattern structure.

The shorting bar of the display device according to another embodiment of the present disclosure may include a multi-layered conductive pattern structure disposed on a substrate and including two or more layers of conductive material patterns with at least one insulating film interposed therebetween, a bank layer covering the multi-layered conductive pattern structure, a first protective film formed on the bank layer, and an encapsulation layer formed on the first protective film.

According to some embodiments of the present disclosure, the multi-layered conductive pattern structure may include: first and second conductive material patterns disposed on a substrate, an interlayer insulating film formed on the first and second conductive material patterns and having first and second contact holes formed therein, third and fourth conductive material patterns formed on the interlayer insulating film to be electrically connected to the first and second conductive material patterns through the first and second contact holes, respectively, a planarization film covering the third and fourth conductive material patterns and having third and fourth contact holes formed therein, and a fifth conductive material pattern formed on the planarization film to be electrically connected to the third and fourth conductive material patterns through the third and fourth contact holes.

According to some embodiments of the present disclosure, the first and second conductive material patterns may be formed of the same material as a gate electrode of a thin-film transistor disposed in the pixel area.

According to some embodiments of the present disclosure, the third and fourth conductive material patterns may be formed of the same material as source and drain electrodes of the thin-film transistor disposed in the pixel area.

According to some embodiments of the present disclosure, the fifth conductive material pattern may be formed of the same material as a first electrode of a light-emitting diode disposed in the pixel area.

The method of manufacturing the shorting bar according to one embodiment of the present disclosure may include forming a multi-layered conductive pattern structure on a substrate, the multi-layered conductive pattern structure including two or more layers of conductive material patterns with at least one insulating film interposed therebetween, and forming a bank-spacer layer on the multi-layered conductive pattern structure to cover the multi-layered conductive pattern structure.

The method of manufacturing the shorting bar according to another embodiment of the present disclosure may include forming a multi-layered conductive pattern structure on a substrate, the multi-layered conductive pattern structure including two or more layers of conductive material patterns with at least one insulating film interposed therebetween, forming a bank layer on the multi-layered conductive pattern structure to cover the multi-layered conductive pattern structure, forming a first protective film on the bank layer, forming an encapsulation layer on the first protective film so as to expose a predetermined portion of the first protective film, and removing the exposed predetermined portion of the first protective film.

According to some embodiments of the present disclosure, the forming of the multi-layered conductive pattern structure may include: forming first and second conductive material patterns on the substrate using the same material as a gate electrode of a thin-film transistor disposed in a pixel area, forming an interlayer insulating film having first and second contact holes formed therein on the first and second conductive material patterns, forming third and fourth conductive material patterns on the interlayer insulating film to be electrically connected to the first and second conductive material patterns through the first and second contact holes, respectively, using the same material as source and drain electrodes of the thin-film transistor disposed in the pixel area, forming a planarization film having third and fourth contact holes formed therein on the third and fourth conductive material patterns to cover the third and fourth conductive material patterns, forming a fifth conductive material pattern on the planarization film to be electrically connected to the third and fourth conductive material patterns through the third and fourth contact holes using the same material as a first electrode of a light-emitting diode disposed in the pixel area.

As is apparent from the above description, the display device and the method of manufacturing the same according to the embodiments of the present disclosure have the following effects.

While a dry etching process is performed on a protective film in a shorting bar area in order to form a test pad, even if over-etching occurs, it may be possible to prevent exposure of a conductive material pattern located on the top layer to the outside or damage to the conductive material pattern located on the top layer because a thick bank or spacer layer covers the conductive material pattern located on the top layer.

Therefore, it may be possible to prevent or reduce occurrence of electrostatic burn.

In addition, it may be possible to prevent or reduce introduction of static electricity into the organic light-emitting display device during various manufacturing and test processes. That is, the internal circuit of the organic light-emitting display device may be protected from static electricity.

The effects achievable through the present disclosure are not limited to the above-mentioned effects, and other various effects may be directly or implicitly disclosed in the above detailed description of the present disclosure.

Those skilled in the art will understand that various modification and alternations are possible from the above description without departing from the technical idea of the present disclosure. Consequently, the technical scope of the present disclosure is defined by the appended claims, not by the detailed description of the present disclosure.

What is claimed is:

1. A display device comprising:
a plurality of gate lines;
a plurality of data lines that cross the plurality of gate lines to define a pixel area; and
a shorting bar to which the plurality of gate lines are electrically connected to temporarily form an equipotential therebetween,
wherein the shorting bar comprises:
a multi-layered conductive pattern structure disposed on a substrate and including two or more layers of conductive material patterns with at least one insulating film interposed therebetween; and
a bank-spacer layer covering the multi-layered conductive pattern structure.

2. The display device according to claim 1, further comprising:
a protective film on the bank-spacer layer.

3. The display device according to claim 1, wherein the multi-layered conductive pattern structure includes:
first and second conductive material patterns disposed on the substrate;
an interlayer insulating film formed on the first and second conductive material patterns and having first and second contact holes formed therein;
third and fourth conductive material patterns formed on the interlayer insulating film to be electrically connected to the first and second conductive material patterns through the first and second contact holes, respectively;
a planarization film covering the third and fourth conductive material patterns and having third and fourth contact holes formed therein; and
a fifth conductive material pattern formed on the planarization film to be electrically connected to the third and fourth conductive material patterns through the third and fourth contact holes,
wherein the fifth conductive material pattern is covered by the bank-spacer layer.

4. The display device according to claim 1, wherein the first and second conductive material patterns comprise a same material as a gate electrode of a thin-film transistor disposed in the pixel area.

5. The display device according to claim 3, wherein the third and fourth conductive material patterns comprise a same material as source and drain electrodes of a thin-film transistor disposed in the pixel area.

6. The display device according to claim 3, wherein the fifth conductive material pattern comprises a same material as a first electrode of a light-emitting diode disposed in the pixel area.

7. A display device comprising:
a plurality of gate lines;
a plurality of data lines that cross the plurality of gate lines to define a pixel area; and
a shorting bar to which the plurality of gate lines is electrically connected to temporarily form an equipotential therebetween,
wherein the shorting bar comprises:
a multi-layered conductive pattern structure disposed on a substrate and including two or more layers of conductive material patterns with at least one insulating film interposed therebetween;
a bank layer covering the multi-layered conductive pattern structure;
a first protective film on the bank layer; and
an encapsulation layer on the first protective film.

8. The display device according to claim 7, further comprising:
a second protective film on the encapsulation layer.

9. The display device according to claim 7, wherein the multi-layered conductive pattern structure includes:
first and second conductive material patterns disposed on the substrate;
an interlayer insulating film formed on the first and second conductive material patterns and having first and second contact holes formed therein;
third and fourth conductive material patterns formed on the interlayer insulating film to be electrically connected to the first and second conductive material patterns through the first and second contact holes, respectively;
a planarization film covering the third and fourth conductive material patterns and having third and fourth contact holes formed therein; and
a fifth conductive material pattern formed on the planarization film to be electrically connected to the third and fourth conductive material patterns through the third and fourth contact holes,
wherein the fifth conductive material pattern is covered by the bank layer.

10. The display device according to claim 9, wherein the first and second conductive material patterns comprise a same material as a gate electrode of a thin-film transistor disposed in the pixel area.

11. The display device according to claim 9, wherein the third and fourth conductive material patterns comprise a same material as source and drain electrodes of a thin-film transistor disposed in the pixel area.

12. The display device according to claim 9, wherein the fifth conductive material pattern comprises a same material as a first electrode of a light-emitting diode disposed in the pixel area.

13. A method of manufacturing a display device comprising a plurality of gate lines and a plurality of data lines disposed in different directions to define a plurality of pixel areas and a shorting bar electrically connected to the plurality of gate lines to temporarily form an equipotential between the plurality of gate lines, the method comprising:
manufacturing the shorting bar by:
forming a multi-layered conductive pattern structure on a substrate, the multi-layered conductive pattern structure including two or more layers of conductive material patterns with at least one insulating film interposed therebetween; and
forming a bank-spacer layer on the multi-layered conductive pattern structure, the bank-spacer layer covering the multi-layered conductive pattern structure.

14. The method according to claim 13, wherein manufacturing the shorting bar further comprises:
forming a protective film on the bank-spacer layer.

15. The method according to claim 13, wherein the forming of the multi-layered conductive pattern structure includes:
forming first and second conductive material patterns on the substrate using a same material as a gate electrode of a thin-film transistor disposed in the plurality of pixel areas;
forming an interlayer insulating film having first and second contact holes formed therein on the first and second conductive material patterns;
forming third and fourth conductive material patterns on the interlayer insulating film to be electrically connected to the first and second conductive material patterns through the first and second contact holes, respectively, using a same material as source and drain electrodes of the thin-film transistor disposed in the plurality of pixel areas;
forming a planarization film having third and fourth contact holes formed therein on the third and fourth conductive material patterns to cover the third and fourth conductive material patterns; and
forming a fifth conductive material pattern on the planarization film to be electrically connected to the third and fourth conductive material patterns through the third and fourth contact holes using a same material as a first electrode of a light-emitting diode disposed in the plurality of pixel areas.

16. A method of manufacturing a display device comprising a plurality of gate lines and a plurality of data lines disposed in different directions to define a plurality of pixel areas and a shorting bar electrically connected to the plurality of gate lines to temporarily form an equipotential between the plurality of gate lines, the method comprising:
manufacturing the shorting bar by:
forming a multi-layered conductive pattern structure on a substrate, the multi-layered conductive pattern structure including two or more layers of conductive material patterns with at least one insulating film interposed therebetween;
forming a bank layer on the multi-layered conductive pattern structure, the bank layer covering the multi-layered conductive pattern structure;
forming a first protective film on the bank layer;
forming an encapsulation layer on the first protective film and exposing a predetermined portion of the first protective film; and
removing the exposed predetermined portion of the first protective film.

17. The method according to claim 16, wherein manufacturing the shorting bar further comprises:
forming a second protective film on the encapsulation layer.

18. The method according to claim 16, wherein the forming of the multi-layered conductive pattern structure includes:
forming first and second conductive material patterns on the substrate using a same material as a gate electrode of a thin-film transistor disposed in the plurality of pixel areas;
forming an interlayer insulating film having first and second contact holes formed therein on the first and second conductive material patterns;
forming third and fourth conductive material patterns on the interlayer insulating film to be electrically connected to the first and second conductive material patterns through the first and second contact holes, respectively, using the same material as source and drain electrodes of the thin-film transistor disposed in the plurality of pixel areas;
forming a planarization film having third and fourth contact holes formed therein on the third and fourth conductive material patterns to cover the third and fourth conductive material patterns; and
forming a fifth conductive material pattern on the planarization film to be electrically connected to the third and fourth conductive material patterns through the third and fourth contact holes using a same material as a first electrode of a light-emitting diode disposed in the plurality of pixel areas.
